(19) United States
(12) Patent Application Publication
(10) Pub. No.: US 2012/0192750 A1
(43) Pub. Date: Aug. 2, 2012

(54) METHODS OF PRODUCING COUNTERMEASURE DECOYS HAVING TAILORED EMISSION SIGNATURES

(75) Inventors: Ender Savrun, Seattle, WA (US); Di Wu, Bothell, WA (US); Stephanie J. Sawhill, Bothell, WA (US)

(73) Assignee: Sienna Technologies, Inc, Woodinville, WA (US)

(21) Appl. No.: 12/246,121

(22) Filed: Oct. 6, 2008

(51) Int. Cl. F42B 4/26; C23C 16/06; B65B 1/04; C23C 16/455

(52) U.S. Cl. 102/336; 427/248.1; 427/250; 427/209; 53/473

(57) ABSTRACT

Methods of producing pyrophoric countermeasure decoy flares include depositing a sculptured thin film of a pyrophoric material onto a substrate using physical vapor deposition. In an example embodiment, physical vapor deposition is performed using a glove box integrated sputtering system. The methods may also include pre-treating the substrate to modify an atomic shadowing effect during pyrophoric material deposition and packaging a plurality of the pyrophoric decoy flares in an airtight container.

### GOVERNMENT INTEREST

The invention described herein was made in the performance of work under Naval Air Warfare Center, U.S. Government Contract No. N68335-06-C-0166. The Government may have rights to portions of this invention.

### FIELD OF THE INVENTION

This invention relates generally to countermeasure decoys and, more specifically, to methods of producing pyrophoric countermeasure decoy flares.

### BACKGROUND OF THE INVENTION

Infrared (IR) decoy flares are used on many military aircraft to protect against attack by heat seeking missiles. They have also more recently been carried on some civilian aircraft operating in potentially hostile environments. One type of flare currently in use is made from a solid pyrotechnic composition of magnesium, TEFLON™ and VITON™. These are commonly called MTV flares and are ejected from an aircraft and simultaneously ignited by the action of a pyrotechnic squib. The use of pyrotechnic flares containing MTV is described in the article “Review on Pyrotechnic Aerial Infrared Decoys,” Propellants, Explosives, Pyrotechnics, v. 26, p. 3-11, Koch, E.-C. (2001). Burning MTV emits IR radiation that is essentially a spectral continuum attenuated by atmospheric absorption. It is intended that the falling flare will cause a missile seeker head to turn away from the target aircraft. The MTV flares are quite effective against older type missiles that seek heat in a single IR band. However, modern missiles employ counter-counter measures (CCM). Their seeker heads typically use more specific spectral bands in an attempt to distinguish between the flare and the aircraft.

Decoy flares containing pyrophoric materials have been developed in an attempt to produce flares with more specific spectral signatures that are effective against modern missiles with refined seeker heads. Pyrophoric flares are usually kept in an airtight storage compartment before deployment because pyrophoric materials ignite when they come in contact with air. Pyrophoric behavior has been observed in a number of metals, such as aluminum, silicon, phosphorus, iron, cobalt, nickel, copper, zinc, titanium, zirconium, hafnium, chromium, manganese, uranium, plutonium, alkali, alkaline earth, and lanthanide metals as described in Department of Energy Handbook 1081-94, “Primer on Spontaneous Heating and Pyrophoricity” (DOE-HDBK-1081-94, 1994). Generally, elements having Pauling electronegativities of 2 or less are sufficiently reactive with oxygen to be pyrophoric. Many alloys and compounds of these metals are also pyrophoric. For example, alloys of lithium, boron, and other alkali metals have been shown to ignite and burn spontaneously in air as described in U.S. Pat. No. 4,960,564 to Sutula et al., incorporated by reference.

Currently, pyrophoric metal containing flares are typically produced using methods such as those described in U.S. Pat. No. 4,895,609 to Baldi. The '609 patent to Baldi teaches a method to make metals pyrophoric by diffusing aluminum or zinc into the metal followed by leaching the aluminum or zinc out of the metal or, alternatively, by reacting the metal with aluminum followed by leaching the aluminum out of the metal to form porous nanostructures. Powdered aluminum and powdered nickel, iron, or cobalt is carried on an elongated support web and reacted by heating for a few seconds to a few minutes, followed by leaching to provide an elongated pyrophoric foil suitable for decoying some types of heat-seeking missiles. However, this process is labor intensive, difficult to control, uses hazardous chemicals such as acids and bases for leaching, and generates a large amount of environmental waste.

### SUMMARY OF THE INVENTION

The present invention includes methods for producing pyrophoric countermeasure decoy flares that include depositing a sculptured thin film (STF) of a pyrophoric material onto a substrate using physical vapor deposition.

Generally, some example embodiments pertain to the production of infrared (IR) decoys with tunable IR emission signatures by physical vapor deposition of sculptured thin films of pyrophoric materials onto a substrate. In some examples, IR decoys are produced with a desired IR emission signature and/or temperature profile by controlling the mass, the thickness, the surface area-to-volume ratios, microstructures, and chemical compositions of STF films, and the thickness, chemical compositions, and surface roughness of substrates to meet specific requirements of an application.

In accordance with some examples of the invention, physical vapor deposition includes sputtering, thermal evaporation, e-beam evaporation, and pulsed laser deposition.

In accordance with other examples of the invention, depositing is conducted with a glove box integrated physical vapor deposition system.

In accordance with still further examples of the invention, depositing is performed with a continuous web coater.

In accordance with yet other examples of the invention, the pyrophoric material is selected from the elements in groups IA, IIA, IIIA, IVA, VA, VIA, VIIA, IB, IIB, IIIB, IVB, and VB of the periodic table of the elements.

In accordance with still another example of the invention, the pyrophoric material is selected from at least one of a mixture or an alloy of elements in groups IA, IIA, IIIA, IVA, VA, VIA, VIIA, VIIIA, IB, IIB, IIIB, IVB, and VB of the periodic table of the elements and depositing is performed using a pre-prepared pyrophoric material deposition source.

In accordance with still further examples of the invention, the substrate is a metal foil selected from at least one of an element, a mixture, or an alloy of elements from groups IA, IIA, IIIA, IVA, VA, VIA, VIIA, VIIIA, IB, IIB, IIIB, IVB, and VB of the periodic table of the elements.

In accordance with yet another example of the invention, the substrate is selected from carbon and a polymer.

In accordance with further examples of the invention, the substrate is selected from a cellulosic polymer and a paper sheet.

In accordance with still further examples of the invention, the substrate and the pyrophoric material are selected such that the flare will have a peak temperature in the range from approximately 400° C. to approximately 1500° C. upon exposure to air.

In accordance with additional examples of the invention, the substrate and the pyrophoric material are selected such that the flare will produce at least one of a visible glow or a flame upon exposure to air.

In accordance with yet other examples of the invention, the substrate and the pyrophoric material are selected such that the flare will not produce a visible glow or a flame upon exposure to air.

In accordance with other examples of the invention, the pyrophoric material is deposited on a single side of the substrate.

In accordance with still other examples of the invention, the pyrophoric material is deposited on both sides of the substrate.

In accordance with still further examples of the invention, the substrate has a thickness in the range from approximately 0.1 μm to approximately 1 mm.

In accordance with yet other examples of the invention, depositing includes depositing a sculptured thin film with a thickness in the range from approximately 1 μm to approximately 500 μm.

In accordance with additional examples of the invention, the substrate is in the shape of a circular disk having a diameter in the range from approximately 0.1″ to approximately 10″.

In accordance with further examples of the invention, the substrate has a rectangular surface having a length and a width in the range from approximately 0.1″ to approximately 10″.

In accordance with further examples of the invention, the substrate is a continuous foil having a width from 0.1″ to 200″, as in the case of web coater.

In accordance with other examples of the invention, the method further includes packaging the decoy flare into a container structured to contain multiple decoy flares.

In accordance with additional examples of the invention, the container is structured to contain between approximately 200 and approximately 5000 decoy flares.

In accordance with yet other examples of the invention, the method further includes pre-treating the substrate before conducting PVD of the STF.

In accordance with still further examples, the invention includes a pyrophoric countermeasure decoy flare that includes a substrate and a sculptured thin film of pyrophoric material deposited on the substrate by physical vapor deposition.

In accordance with other examples of the invention, physical vapor deposition includes sputtering, thermal evaporation, e-beam evaporation, and pulsed laser deposition.

These and other examples of the invention will be described in further detail below.

### BRIEF DESCRIPTION OF THE DRAWINGS

Preferred and alternative examples of the present invention are described in detail below with reference to the following drawings:

FIG. 1 is a diagram of a glove box integrated sputtering system used in accordance with an embodiment of the invention;

FIG. 2 is a diagram of a circular substrate before deposition of a pyrophoric material;

FIG. 3 is a diagram of a pyrophoric decoy flare having a rectangular surface, formed in accordance with an example embodiment of the invention;

FIG. 4 is a diagram showing multiple pyrophoric decoy flares packaged in an airtight container;

FIGS. 5 and 6 are flowcharts of a method of producing pyrophoric decoy flares in accordance with an embodiment of the invention;

FIG. 7 is a diagram showing an example time-temperature profile of a pyrophoric decoy flare formed in accordance with an example embodiment of the invention;

FIG. 8 is a diagram showing an example time-temperature profile of a pyrophoric decoy flare formed in accordance with an alternate example embodiment of the invention;

FIG. 9 is a diagram showing an example time-temperature profile of a pyrophoric decoy flare formed in accordance with an alternate example embodiment of the invention;

FIG. 10 is a top view of an example decoy in accordance with prior methods;

FIG. 11 is a sectional view of an example decoy of FIG. 10;

FIG. 12 is a top view of an exemplary decoy in accordance with the invention; and

FIG. 13 is a sectional view of the exemplary decoy of FIG. 12.

### DETAILED DESCRIPTION OF THE PREFERRED EMBODIMENT

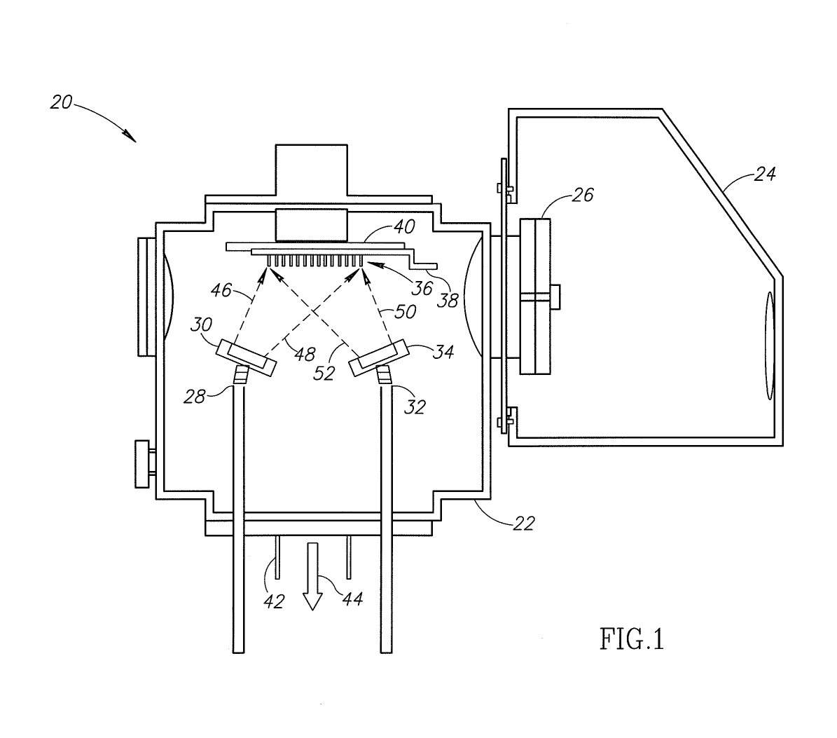

FIG. 1 is a diagram of a glove box integrated sputtering system 20 used in accordance with an embodiment of the invention. The system 20 includes a deposition chamber 22 connected to a glove box 24 through a loadlock door 26. The deposition chamber 22 includes a first sputtering gun 28 used in conjunction with a first target source material 30. The deposition chamber 22 also includes a second sputtering gun 32 used in conjunction with a second target source material 34. At least one substrate 36 is held by a substrate holder 38 that is connected to a substrate holder mounting fixture 40. A connection port 42 is used to connect the deposition chamber 22 to other systems such as a vacuum pump (not shown), for example. An arrow 44 indicates a direction of air flow when a vacuum pump connected to the port 42 begins operation. Additional components (not shown) may also be present in or attached to the deposition chamber 22 that provide control over the internal environment of the deposition chamber 22. Such additional components may include additional ports to allow introduction of an inert gas such as Argon (Ar) into the chamber 22 or components that provide control for the circulation of any gasses or air present in the chamber 22.

The deposition flux incident angles 46, 48, 50, 52 indicate a general path of travel of sputtered or deposited material from the target 34 toward the substrate 36. By using two targets trained angularly toward a central region between them, the two targets are able to coat both sides of the substrate at the same time. The particular angles of the path of travel with respect to the plane defined by the substrate results in a deposition pattern producing interstitial sites, pores, or gaps in the buildup of deposited material. Thus, by varying the angle of incidence the pores can be adjusted as desired. In turn, the resulting adjusted material will have a different thermal signature, as desired.

In this example system 20, the two sputtering guns 28, 32 allow deposition of a pyrophoric material on both sides of the substrate 36. Use of only one of the sputtering guns 28, 32, or a system containing only one sputtering gun would allow deposition of a pyrophoric material on a single side of the substrate 36.

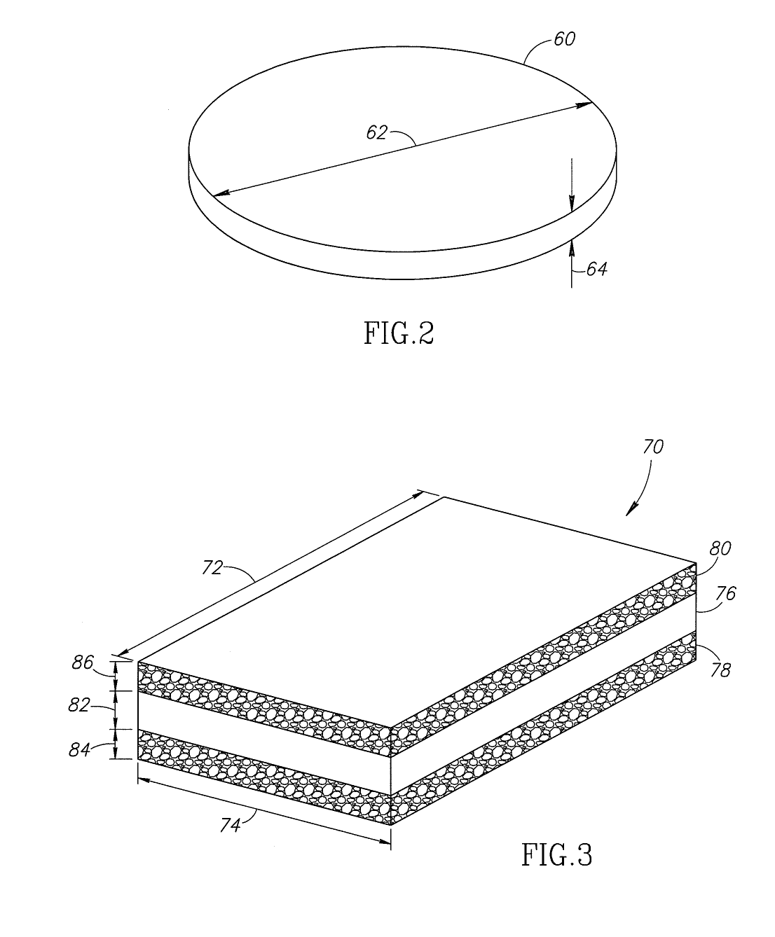

FIG. 2 is a diagram of a circular substrate 60 before deposition of a pyrophoric material. The circular substrate 60 has a diameter 62 that ranges from approximately 0.1 inches (2.54 mm) to approximately 10 inches (254 mm) and a thickness 64 that ranges from approximately 0.1 μm to approximately 1 mm in some embodiments of the invention.

FIG. 3 is a diagram of a pyrophoric decoy flare 70 having a rectangular surface and formed in accordance with an example embodiment of the invention. The rectangular surface of the decoy flare 70 has a length 72 and a width 74 that each range from approximately 0.1 inches (2.54 mm) to approximately 10 inches (254 mm) in some embodiments. The decoy flare 70 includes a substrate 76 also having length 72 and width 74. A first pyrophoric STF layer 78 is deposited on a first side of the substrate 76 and a second pyrophoric STF layer 80 is deposited on a second side of the substrate 76. The substrate 76 has a thickness 82 that ranges from approximately 0.1 μm to approximately 1 mm in some embodiments of the invention. The first pyrophoric STF layer 78 has a thickness 84 and the second pyrophoric STF layer 80 has a thickness 86, each of which range from approximately 1 μm to approximately 500 μm in some embodiments of the invention. The substrate 76 and the layers 78 and 80 are shown in a representational form and are not drawn to scale.

STF films are highly porous, thin films and their nanostructures can be engineered to provide extremely high surface area-to-volume ratios, i.e., >500 cm² per cm² of covered substrate as described in Harris, K. D., et al (2001) “Porous thin films for thermal barrier coatings”, Surf. And Coat. Tech, 138, p. 185-191. STF films of pyrophoric materials with controlled chemical compositions and tailored surface area-to-volume ratios can be prepared by physical vapor deposition (PVD) techniques in a clean, one-step process. One mechanism behind porous STF formation during a PVD process is atomic self-shielding or atomic shadowing. The stronger atomic shadowing effect and the lower mobility of ad-atoms on the STF growing surfaces will lead to higher porosity. Generally, the high flux incident angle, low chamber pressure, and large substrate to source distance will enhance atomic shadowing effect, and the low substrate temperature and high deposition rate will lower the mobility of ad-atoms on the STF growing surfaces. Higher porosity and thicker STF films will leads to higher peak temperature of an IR signature. The described process can vary the porosity between 0% to 90% by changing substrate temperatures (<700oC), flux incident angle (30°to 90°), deposition rate (0.1 micron/h to 500 microns/h), substrate-to-source distance (>2 inches), chamber pressure (<1 atm), and substrate rotation (0-1000 rpm).

The pyrophoric nature of these materials allows the spontaneous heating of the deposited films, and subsequently, the substrates (e.g. metal and/or polymer foils) upon exposure to air to give specific IR signatures for decoying heat-seeking missiles.

Generally, pyrophoricity depends on the surface area and chemical composition of a pyrophoric material. Physical vapor deposition can deposit reproducible thin film coatings with closely controlled chemical compositions, microstructure, and morphologies and uniform thickness over extended surfaces on a variety of substrates. In some embodiments, PVD is used to deposit pyrophoric STF layers with controlled chemical compositions and tailored surface-to-volume ratios to allow spontaneous heating of the films, and subsequently, the substrates, to give a specific thermal signature. Examples of physical vapor deposition techniques in addition to sputtering include thermal evaporation, e-beam evaporation and pulse laser deposition. All these techniques have substantially similar process mechanisms. The main difference among these PVD techniques is the way to generate atomic flux of the deposited material from the solid targets/sources: thermal evaporation uses thermal heating, sputtering uses ion bombardment, e-beam evaporation uses electron bombardment, pulse laser deposition uses laser to generate atomic flux from the solid targets/sources. To form STF films, they all require common process parameters: vapor flux incident angle between 30° and 90°, substrate temperature less than 700oC, reduced pressure environment (1 atm<) to have vapor flux traveling in a line-of-sight, substrate-to-target distance greater than 2 inches, and substrate rotation from 0 rpm to 1000 rpm.

PVD can also be adapted to continuous web coaters to economically produce large quantities of the STF layers on a substrate. The process parameters will the same as those for a conventional PVD STF deposition except for the substrate will be moved at prescribed speeds during the deposition. Some example embodiments, include using a continuous web coater to apply the pyrophoric STF to a substrate.

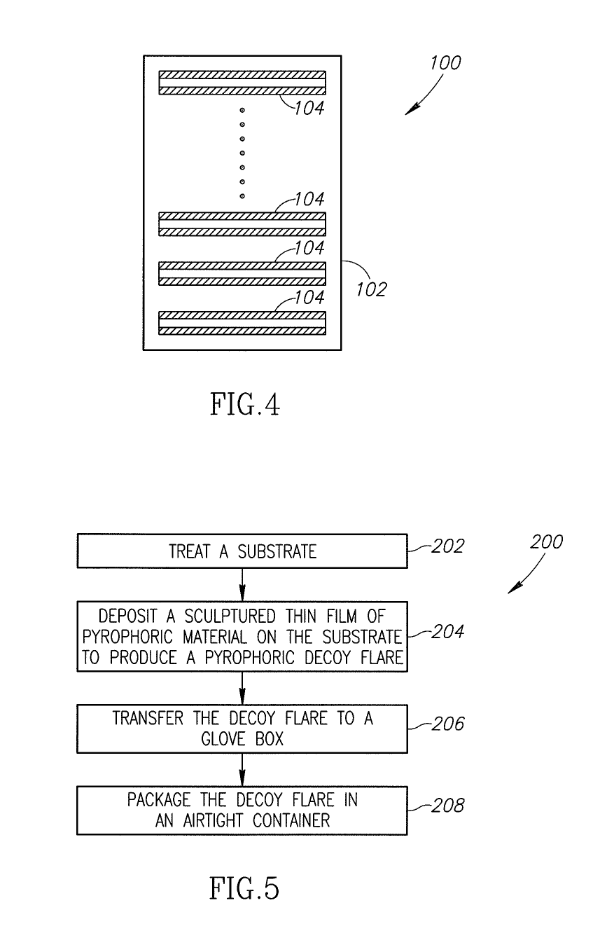

FIG. 4 is a diagram showing a cross-sectional representation of a pyrophoric decoy flare assembly 100. The pyrophoric decoy flare assembly 100 includes an airtight container 102 into which multiple pyrophoric decoy flares 104 are packaged.

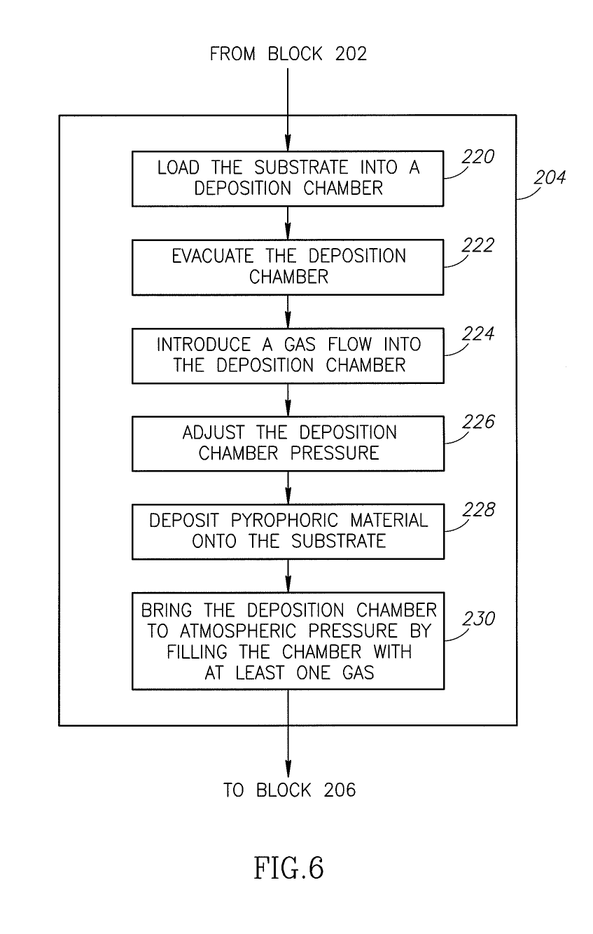

FIGS. 5 and 6 are flowcharts of a method 200 of producing pyrophoric decoy flares in accordance with an embodiment of the invention. First, at a block 202, a substrate, such as the substrate 36, 60, or 70, is optionally pre-treated to modify the atomic shadowing effect during pyrophoric material STF deposition to control the surface-to-volume ratio of the deposited STF layer. In one example, an iron (Fe) substrate surface is roughened by pickling with concentrated sulfuric acid for one minute. In various example embodiments of the invention, the substrate may include at least one of: foils made of elements in groups IA, IIA, IIIA, IVA, VA, VIA, VIIA, VIIIA, IB, IIB, IIIB, IVB, and VB; mixtures of such elements; alloys of such elements; a carbon; a polymer; a cellulosic polymer; or a paper sheet. However, other substrate materials may also be used in other embodiments. Next, at a block 204, a STF of pyrophoric material is deposited on the substrate to produce a pyrophoric decoy flare, such as the flare 70 shown in FIG. 3, for example. In an example embodiment, the STF of pyrophoric material is selected from an element in groups IA, IIA, IIIA, IVA, VA, VIA, VIIA, IB, IIB, IIIB, IVB, and VB or a mixture or alloy of elements in groups IA, IIA, IIIA, IVA, VA, VIA, VIIA, VIIIA, IB, IIB, IIIB, IVB, and VB. Then, at a block 206, the decoy flare is transferred to a glove box, such as the glove box 24 shown in FIG. 1. Next, at block 208 the decoy flare is packaged in an airtight container, such as the container 102 shown in FIG. 4.

Referring now to FIG. 6, it can be seen that depositing pyrophoric material on the substrate in the block 204 includes a number of steps in an example embodiment. First, at a block 220, the substrate is loaded into a deposition chamber, such as onto the substrate holder 38 in the deposition chamber 22 shown in FIG. 1. Then, at a block 222, the deposition chamber is evacuated. This may be performed using a vacuum pump, such as by attaching a vacuum pump to the port 42, for example. Next, at a block 224, a gas flow is introduced into the deposition chamber. In one example, Argon (Ar) gas is introduced, flowing at a rate of approximately 15 standard cubic centimeters per minute (sccm). Then, at a block 226, the deposition chamber pressure is adjusted. Next, at a block 228, a pyrophoric material is deposited onto the substrate, such as by using the sputtering guns 28 and 32 shown in FIG. 1, for example. Then, at a block 230, after a desired thickness of pyrophoric material on the substrate has been reached, the deposition chamber is brought to atmospheric pressure by filling the chamber with at least one gas. In one example, the deposition chamber is filled with Ar gas until the pressure in the chamber reaches atmospheric pressure.

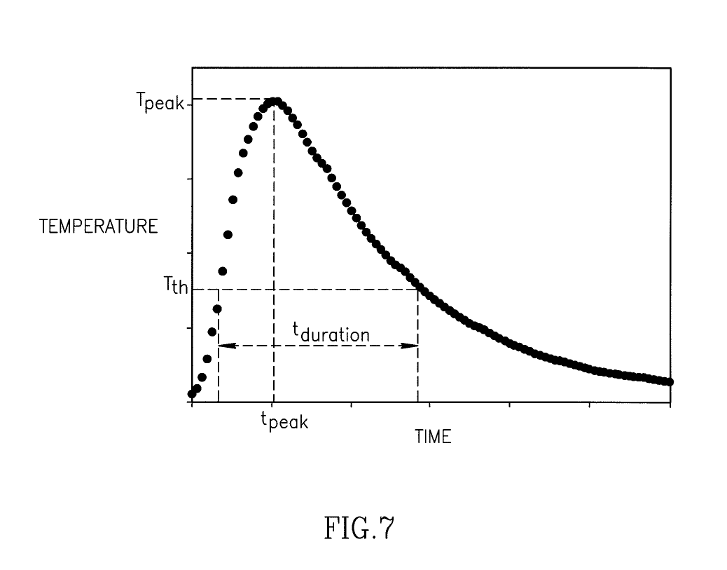

FIG. 7 is a diagram showing an example time-temperature profile of a pyrophoric decoy flare formed in accordance with an example embodiment of the invention. A time-temperature profile of an IR decoy upon exposure to air is one way to characterize its IR signature. Tₚₑₐₖ is the peak temperature, tₚₑₐₖ is the rise time for the decoy to reach the peak temperature, and t_{duration} is the duration time of temperature higher than a defined threshold temperature, Tₜₕ. The time-temperature profile shown in FIG. 7 is representational, with arbitrary units for time and temperature.

The IR signature or time-temperature profile of an STF film IR decoy may be changed to match the required IR signatures for a given application. The IR signature of the STF film IR decoys is tailored to a particular application by controlling the chemical composition, the mass, the thickness, the surface area-to-volume ratios (porosity) of deposited STF films, and the thickness and chemical compositions of substrates to meet specific requirements of an application. The chemical composition, the mass, the thickness, and the surface area-to-volume ratios (porosity) of the STF films are controlled by controlling the deposition parameters during a physical vapor deposition process.

Typical process parameters are deposition flux incident angle, substrate temperature, deposition rate, deposition time, substrate-to-target distance, chamber pressure, substrate rotation, and deposition source materials. For example, the mass and thickness from 0.1 micron to 500 microns of the STF films are determined by deposition rate, which is in turn determined by deposition power and source material, and deposition time. Surface area-to-volume ratios (porosity) and nanostructures of the deposited STF films are determined by deposition flux incident angle (30°-90°), substrate temperature (<700° C.), deposition rate (0.1 micron/h to 500 microns/h), substrate-to-source distance (>2 inches), chamber pressure <1 atm), and substrate rotation (0-1000 rpm). The stronger atomic shadowing effect and the lower mobility of ad-atoms on the STF growing surfaces will lead to higher porosity. Generally, the high flux incident angle, low chamber pressure, and large substrate to source distance will enhance atomic shadowing effect, and the low substrate temperature and high deposition rate will lower the mobility of ad-atoms on the STF growing surfaces. Higher porosity and thicker STF films will leads to higher peak temperature of an IR signature.

As an example, Fe—Ti STF films reach higher peak temperatures (Tₚₑₐₖ) than Fe—Mn STF films. As the Ti concentration in the Fe—Ti source or in the STF film increases Tₚₑₐₖ increases. Pyrophoric STF films with high surface-area-to-volume ratio (high porosity) and large thicknesses favoring fast air diffusion on thin substrates will lead to high peak temperatures, Tₚₑₐₖ, and to short rise times, tₚₑₐₖ. The duration (t_{duration}) is mainly determined by the mass and thickness of the STF films. Two more specific examples of methods of creating pyrophoric decoy flares using Fe—Mn and Fe—Ti as the pyrophoric material are discussed below, but the invention is not meant to be limited to the details described therein.

In a first example, Fe—Mn (87% wt. Fe-13% wt. Mn) STFs are deposited on 25 micron (0.025 mm) thick iron substrates from a source having the same chemical composition using a magnetron sputtering technique as schematically shown in FIG. 1 and described with reference to FIGS. 5 and 6. The sputtering sources are typically manufactured from commercially available Fe—Mn plates with a Mn composition of 13%. The process parameters are 300 Watt DC power to each sputtering gun, a 5.5″ substrate-to-source distance, a 60° deposition flux incident angle, and a 0 rpm substrate rotation.

After loading the Fe substrates, the deposition chamber 22 is evacuated to a base pressure of ˜10⁻⁶ Torr and a 15 sccm Ar flow is intruduced into the chamber 22 followed by adjusting the chamber 22 pressure to be 10 mTorr. Under these conditions, 30 micron (0.03 mm) thick Fe:Mn STFs are deposited on the iron substrates. Upon completion of deposition, the deposition chamber 22 is filled with Ar to the atomsperic pressure. The completed STF decoys are then transferred to the glove box 24 through the loadlock door 26 in an Ar environment. Inside the glove box 26, the STF decoys are packaged into an air-tight container, such as the container 102 shown in FIG. 4.

In a second example, Fe—Ti (60% wt. Fe—40% wt. Ti) STFs are deposited on 12 micron (0.012 mm) thick Aluminum substrate using a magnetron sputtering technique. The sputtering targets are manufactured from Fe—Ti alloy with a Ti composition of 40%. The process parameters are 450 Watt DC power to each gun, a 5.5″ substrate-to-gun distance, and a 70° deposition flux incident angle.

After loading the aluminum substrates, the deposition chamber 22 is evacuated to a base pressure of ˜10⁻⁶ Torr and a 15 sccm Ar flow is intruduced into the chamber 22 followed by adjusting the chamber pressure to be 10 mTorr. Under these conditions, 20 micron (0.02 mm) thick Fe—Ti STFs are deposited on the substrates. Upon completion of deposition, the deposition chamber 22 is filled with Ar to the atomsperic pressure. The completed STF decoys are then transferred to the glove box 24 through the loadlock door 26 in an Ar environment. Inside the glove box 26, the STF decoys are packaged in a air tight container, such as the container 102 shown in FIG. 4.

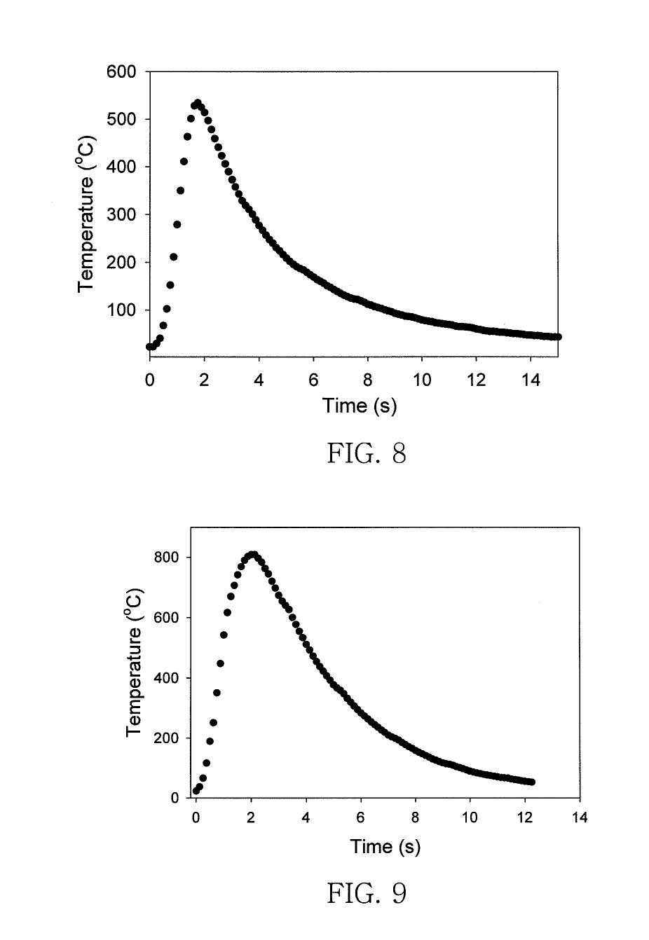

The first and second examples described above produce the first and second time-temperature profiles illustrated in FIGS. 8 and 9, respectively. As shown, the peak temperature and the duration differs between the two profiles.

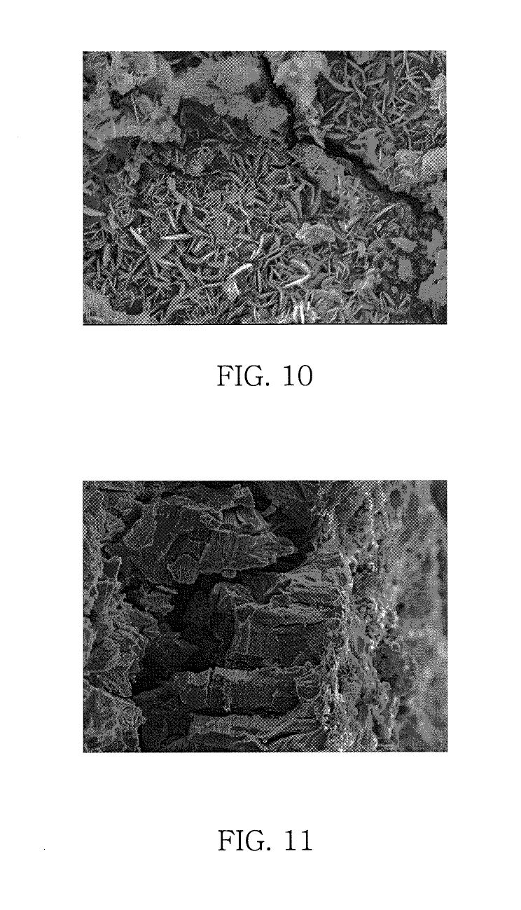

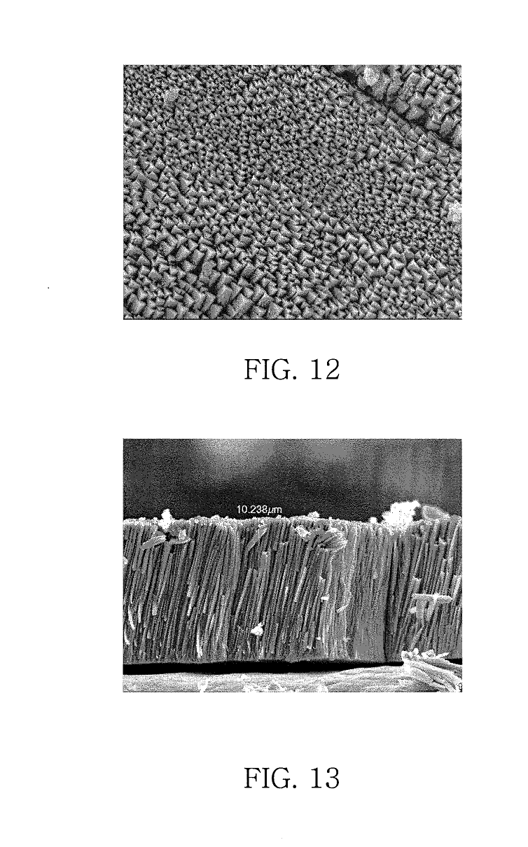

FIGS. 10 and 11 illustrate a typical decoy made in accordance with prior art methods of manufacture. A top perspective view is provided in FIG. 10; a sectional view is provided in FIG. 11. As is readily apparent, the structure of the coating on the substrate is not uniform. The distribution is uneven and the space between grains varies widely. By contrast, FIGS. 12 and 13 illustrate a corresponding top and sectional view of a decoy made in accordance with the present invention. As the images illustrate, the coating is uniformly distributed and much more evenly aligned. The even distribution and alignment allows a much better control of the behavior of the resulting product, thereby allowing a much improved ability to design a desired time-temperature profile.

While the preferred embodiment of the invention has been illustrated and described, as noted above, many changes can be made without departing from the spirit and scope of the invention. For example, other substrate materials or pyrophoric materials may be used in some embodiments. Also, some method steps may be performed in a different order than that described or concurrently with other steps. Accordingly, the scope of the invention is not limited by the disclosure of the preferred embodiment. Instead, the invention should be determined entirely by reference to the claims that follow.

The embodiments of the invention in which an exclusive property or privilege is claimed are defined as follows:

1. A method of producing pyrophoric countermeasure decoy flares, the method comprising:
depositing a sculptured thin film of a pyrophoric material onto a substrate using physical vapor deposition.

2. The method of claim 1, wherein physical vapor deposition includes sputtering.

3. The method of claim 2, wherein depositing is conducted with a glove box integrated sputtering system.

4. The method of claim 2, wherein depositing is performed with a continuous web coater.

5. The method of claim 2, wherein the pyrophoric material is selected from the elements in groups IA, IIA, IIIA, IVA, VA, VIA, VIIA, IB, IIB, IIIB, IVB, and VB of the periodic table of the elements.

6. The method of claim 2, wherein the pyrophoric material is selected from at least one of a mixture or an alloy of elements in groups IA, IIA, IIIA, IVA, VA, VIA, VIIA, VIIIA, IB, IIB, IIIB, IVB, and VB of the periodic table of the elements and wherein depositing is performed using a pre-prepared pyrophoric material deposition source.

7. The method of claim 2, wherein the substrate is a metal foil selected from at least one of an element, a mixture, or an alloy of elements from groups IA, IIA, IIIA, IVA, VA, VIA, VIIA, VIIIA, IB, IIB, IIIB, IVB, and VB of the periodic table of the elements.

8. The method of claim 2, wherein the substrate is selected from carbon and a polymer.

9. The method of claim 2, wherein the substrate is selected from a cellulosic polymer and a paper sheet.

10. The method of claim 2, wherein the substrate and the pyrophoric material are selected such that the flare will have a peak temperature in the range from approximately 400° C. to approximately 1500° C. upon exposure to air.

11. The method of claim 2, wherein the substrate and the pyrophoric material are selected such that the flare will produce at least one of a visible glow or a flame upon exposure to air.

12. The method of claim 2, wherein the substrate and the pyrophoric material are selected such that the flare will not produce a visible glow or a flame upon exposure to air.

13. The method of claim 2, wherein the pyrophoric material is deposited on a single side of the substrate.

14. The method of claim 2, wherein the pyrophoric material is deposited on both sides of the substrate.

15. The method of claim 2, wherein the substrate has a thickness in the range from approximately 0.1 μm to approximately 1 mm.

16. The method of claim 2, wherein depositing includes depositing a sculptured thin film with a thickness in the range from approximately 1 μm to approximately 500 μm.

17. The method of claim 2, wherein the substrate is in the shape of a circular disk having a diameter in the range from approximately 0.1″ to approximately 3″.

18. The method of claim 2, wherein the substrate has a rectangular surface having a length and a width-in the range from approximately 0.1″ to approximately 3″.

19. The method of claim 2, further comprising packaging the decoy flare into a container structured to contain multiple decoy flares.

20. The method of claim 19, wherein the container is structured to contain between approximately 200 and approximately 5000 decoy flares.

21. A pyrophoric countermeasure decoy flare comprising:
a substrate; and
a sculptured thin film of pyrophoric material deposited on the substrate by physical vapor deposition.

22. The decoy flare of claim 21, wherein physical vapor deposition includes sputtering thermal evaporation, e-beam evaporation, and pulsed laser deposition.
